(19) United States
(12) Patent Application Publication
(10) Pub. No.: US 2007/0243663 A1
(43) Pub. Date: Oct. 18, 2007

(54) Method of wafer level chip size packaging

(76) Inventor: Hsih-Chun Chen, Taipei City (TW)

Correspondence Address: BIRCH STEWART KOLASCH & BIRCH, PO BOX 747, FALLS CHURCH, VA, 22040-0747, US

(21) Appl. No.: 11/783,249

(22) Filed: Apr. 6, 2007

(30) Foreign Application Priority Data
Apr. 13, 2006 (TW) 95113087

(51) Int. Cl. H01L 21/00

(52) U.S. Cl. 438/106

(57) ABSTRACT

A method of wafer level chip size packaging includes the steps of: grinding a wafer on a back surface to a predetermined thickness; sawing the wafer into a plurality of wafer slices; spray coating a photo resist layer on top of the wafer slice; applying a lithography process to form contact windows on the wafer slice; forming a pattern on the wafer slice by printing or sputtering, in which bottom ends of the pattern are connected with the respective contact windows and an upper surface of the pattern forms protrusively a plurality of under bump metals (UBM); spray coating a solder mask on top of the pattern; applying another lithography process to form apertures on the respective UBMs; implanting solder balls to the respective apertures by printing; and finally sawing the wafer slice into separate dies.

This application claims the benefit of Taiwan Patent Application Serial No. 95113087, filed Apr. 13, 2006, the subject matter of which is incorporated herein by reference.

### BACKGROUND OF THE INVENTION

(1) Field of the Invention

The invention relates to a package method for semiconductors, and more particularly to a method of wafer level chip size (scale) packaging.

(2) Description of the Prior Art

Chip scale package, or chip size package, (CSP) is manufactured by a semiconductor process (chip scale packaging) that puts the encapsulation and testing step ahead of the die cutting step. For the die sizes before and after the cutting are almost the same, the CSP products can meet the mainstream fashion in lesser weight and slimness. The CSP does not affect the electric performance of the products. Also, for, in a single CSP step, a large amount of the dies can be produced at the same time, the production efficiency can be greatly increased and the cost can be substantially reduced on the other hand. Therefore, the CSP as a new generation package has gradually replaced both the lead-frame package and the substrate package in the semiconductor packaging industry.

Referring now to FIG. 1, a cross section view of a portion of a typical wafer 1 with complete circuiting is shown. The wafer 1 includes a plurality of dies 10 (four shown in the figure). Each of the dies 10 is covered by a circuiting layer 12 and a plurality of on-top pads 14 (two shown in each die 10). Further, a protection layer 16 is formed to shield the circuiting layer 12 as well as the pads 14.

Referring now to FIGS. 2A-2H, a typical wafer scale packaging is shown step by step. The wafer scale packaging comprising the steps of: grinding the wafer 1 at the die side to have a predetermined thickness (FIG. 2A, in which the dotted portion are those to be removed); forming a photo resist layer 18 on top of the protection layer 16 (FIG. 2B); applying a lo lithography process to form contact windows 20 on the respective pads 14 (FIG. 2C); sputtering an Al-alloy pattern 22 on top of the protection layer 16 (FIG. 2D), in which bottom ends of the pattern 22 are connected with the respective contact windows 20 and an upper surface of the pattern 22 forms protrusively a plurality of metal pads 24; spin-coating a solder mask 26 on top of the Al-alloy pattern 22 (FIG. 2E); applying another lithography process to form apertures 28 on the respective metal pads 24 (FIG. 2F); implanting solder balls 29 to the respective apertures 28 (FIG. 2G); and finally sawing the wafer 1 into separate dies 10 (FIG. 2H).

In the foregoing manufacturing process, the lithography process generally includes steps of soft bake, exposure and development, and hard bake. The pattern 22 on the protection layer 16 can be a single-layer circuit or a multi-layer circuit. The metal pads 24 can be integrally formed as a Zn—Ni layer by chemical deposition.

In addition, a photo resist spinner is needed to process the spin coating process, a sputter is needed to process the sputtering process, and an auto-alignment exposure machine is needed to process the lithography process. The cost for all the aforesaid machinery is huge, and the follow-up mega investment upon the maintenance or repurchase of machinery for new-generation wafer size can be definitely foreseen. For example, machinery for an 8-in wafer foundry are not applicable anymore to a new 12-in wafer foundry. Those machinery include machines for manufacturing, packaging, and all other works involved in semiconductor production.

Therefore, how to optimally use the packaging facilities, especially in having them perform packaging of new-specs wafers, are definitely worth the person skilled in the art to be devoted to.

### SUMMARY OF THE INVENTION

Accordingly, it is an object of the present invention to provide a method of wafer level chip size packaging that is applicable to all specs of packages.

In the present invention, the method of wafer level chip size packaging includes the steps of: grinding a wafer on a back surface to a predetermined thickness; sawing the wafer into a plurality of wafer slices; spray coating a photo resist layer on top of the wafer slice; applying a lithography process to form contact windows on the wafer slice; forming a pattern on the wafer slice by printing or sputtering, in which bottom ends of the pattern are connected with the respective contact windows and an upper surface of the pattern forms protrusively a plurality of under bump metals (UBM); spray coating a solder mask on top of the pattern; applying another lithography process to form apertures on the respective UBMs; implanting solder balls to the respective apertures by printing; and finally sawing the wafer slice into separate dies.

In an embodiment of the present invention, the wafer can be symmetrically sawed at least twice into four more wafer slices, such that each of the wafer slice would have a maximum size of ¼ wafer. Upon such an arrangement, the wafer slice would be made to a size that is fitted to any existing package machinery.

In the present invention, a photo resist spray coater can be used to perform the spray coating of the photo resist on the wafer slice. In the lithography process of the present invention, soft bake, exposure and development, and hard bake are included, in which a manual alignment exposure machine can be used to perform the exposure.

Further, the pattern of the wafer slice in accordance with the present invention can be a single-layer circuit, or a multi-layer circuit. In the case that the pattern is a multi-layer circuit, repeating the lithography process and the pattern-forming process as described above would be needed. Also, on the UBM, a layer of Zn and Ni can be chemically deposited in advance and then the solder balls can be implanted by a solder paste printing and reflow process.

In the present invention, any size of wafer can be sawed into a plurality of the wafer slices having a proper size able to be packaged by existing package machines. Upon such an arrangement, additional cost for purchasing machinery for new-generation wafer size can be thus waived.

All these objects are achieved by the method of wafer level chip size packaging described below.

### BRIEF DESCRIPTION OF THE DRAWINGS

The present invention will now be specified with reference to its preferred embodiment illustrated in the drawings, in which:

FIG. 1 is a schematic cross section view of a portion of a typical wafer with complete circuiting;

FIG. 2A-FIG. 2H show step-by-step a typical wafer scale packaging;

FIG. 3A-FIG. 3I show step-by-step a preferred method of wafer level chip size packaging in accordance with the present invention; and

FIG. 4 shows a wafer sawed symmetrically into four wafer slices.

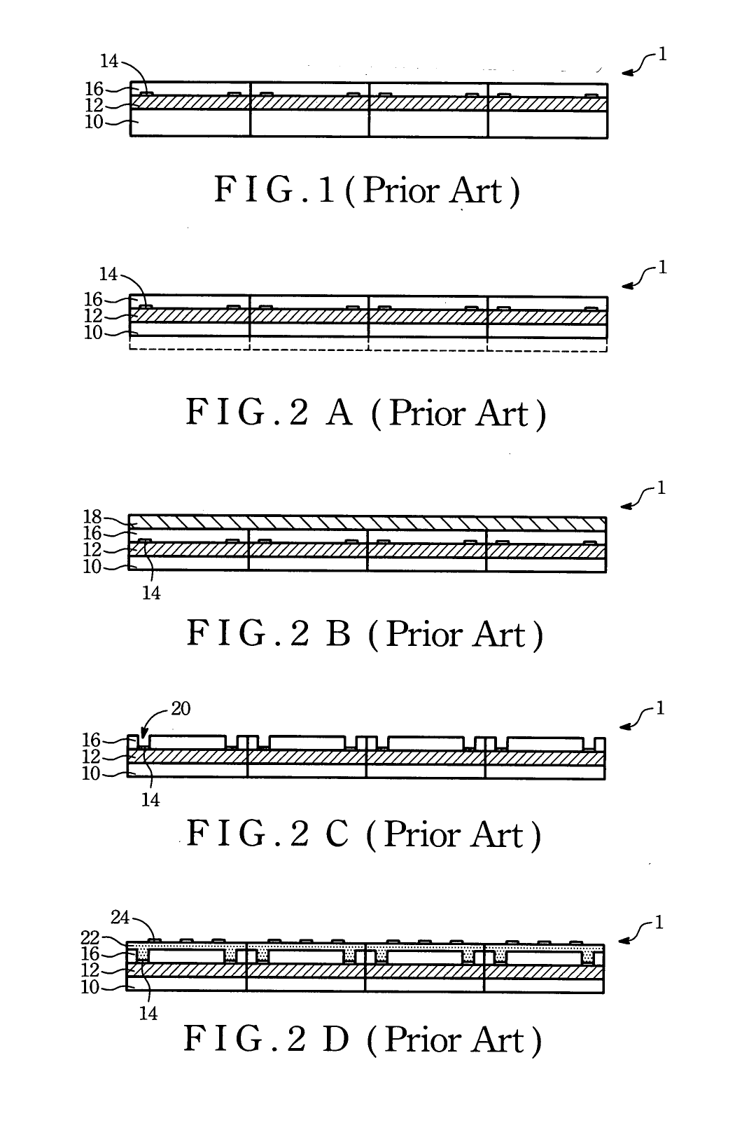

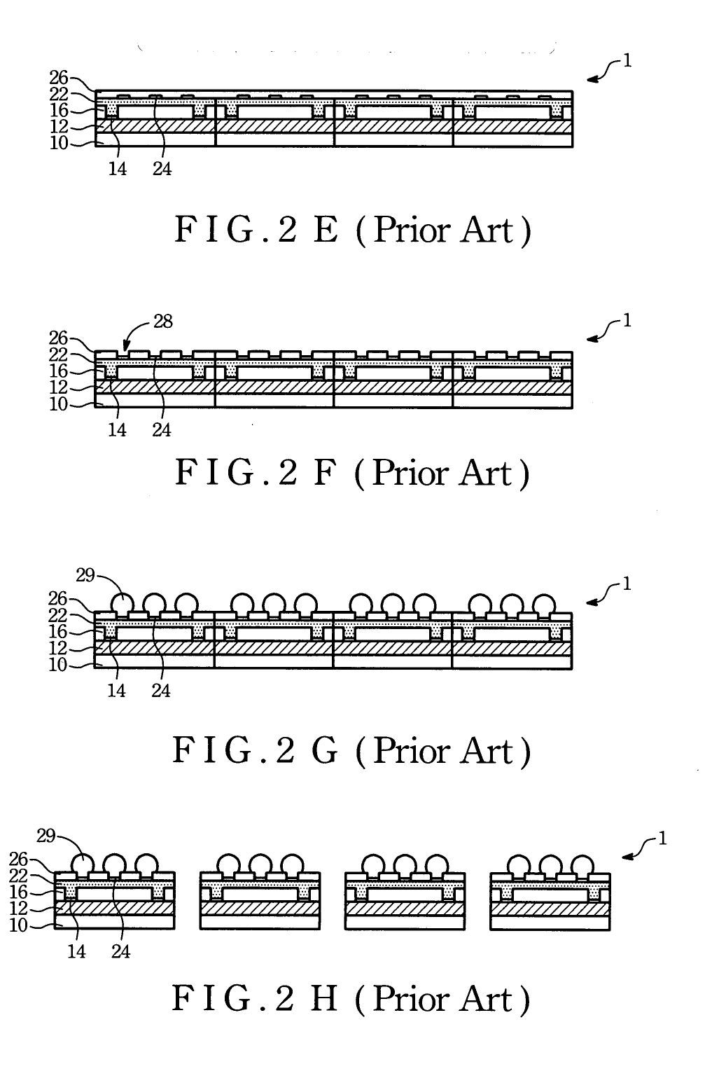

### DESCRIPTION OF THE PREFERRED EMBODIMENT

The invention disclosed herein is directed to a method of wafer level chip size packaging. In the following description, numerous details are set forth in order to provide a thorough understanding of the present invention. It will be appreciated by one skilled in the art that variations of these specific details are possible while still achieving the results of the present invention. In other instance, well-known components are not described in detail in order not to unnecessarily obscure the present invention.

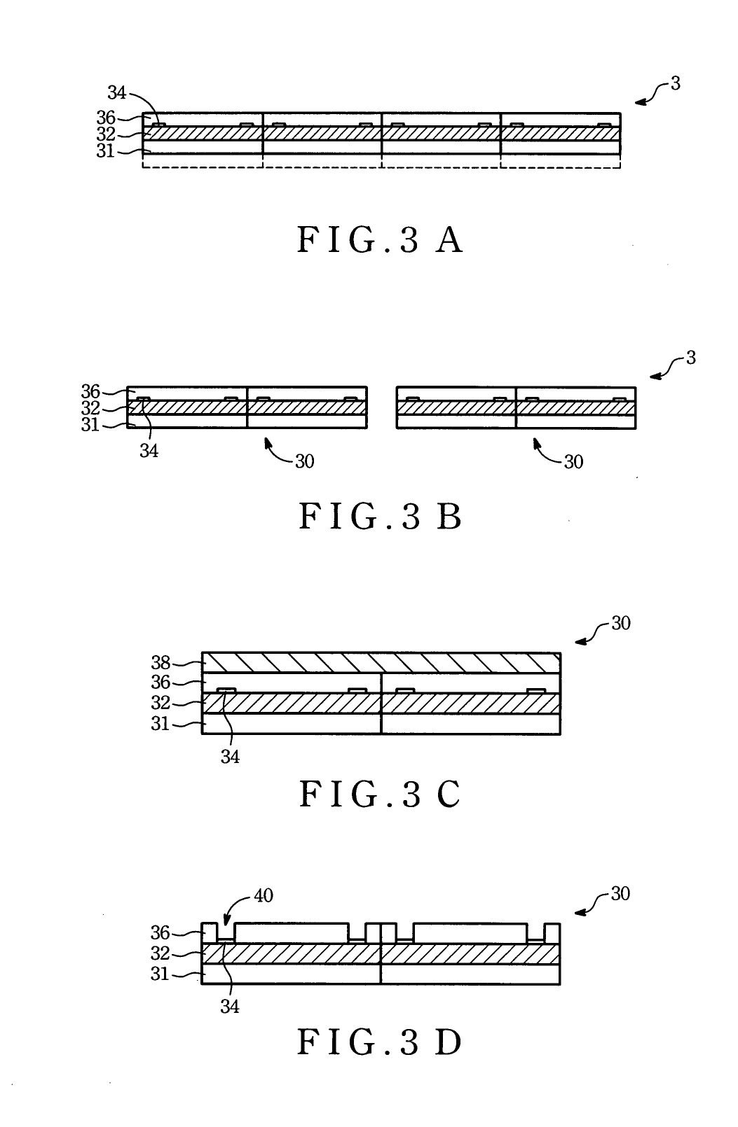

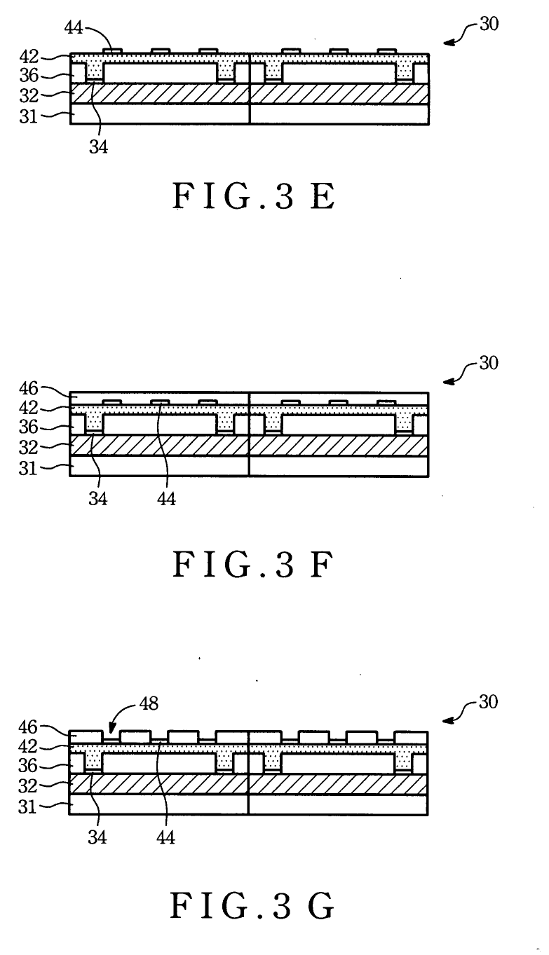

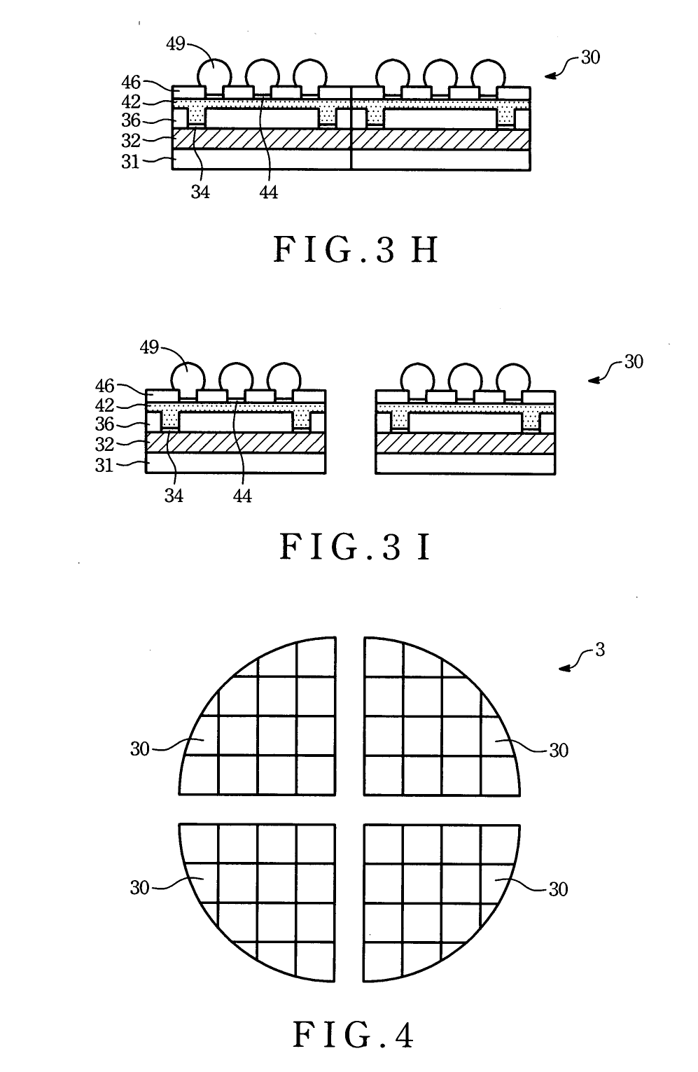

Referring now to FIG. 3A-FIG. 3I, a preferred method of wafer level chip size packaging in accordance with the present invention is shown step by step. As shown, the wafer 3 includes a plurality of dies 31 (four shown in the figure for representation). Each of the die 31 has undergone a complete IC manufacturing process to have an integrated circuit layer 32 with a plurality of on-top pads 34. A protection layer 36 is further formed on the integrated circuit layer 32.

In the present invention, the method of wafer level chip size packaging includes the steps of: grinding the wafer 3 on a back surface (the dotted-line side) to a predetermined thickness (FIG. 3A); sawing the wafer 3 into a plurality of wafer slices 30 (FIG. 3B); spray coating a photo resist layer 38 on top of the wafer slice 30 (FIG. 3C); applying a lithography process to form contact windows 40 on the wafer slice 30 (FIG. 3D); forming a pattern 42 on the wafer slice 30 by printing or sputtering (FIG. 3E), in which bottom ends (the lower ends in the figure) of the pattern 42 are connected with the respective contact windows 40 and an upper surface of the pattern 42 forms protrusively a plurality of under bump metals (UBM) 44; spray coating a solder mask on top of the pattern 42 as well as the wafer slice 30 (FIG. 3F); applying another lithography process to form apertures (or vias) 48 on the respective UBMs 44 (FIG. 3G); implanting solder balls 49 to the respective apertures 48; and finally sawing the wafer slice 30 into separate dies 31 (FIG. 3I).

Referring now to FIG. 4, for example, the wafer 3 is symmetrically sawed twice into four wafer slices 30, in which each of the wafer slices 30 would be ¼ of the original wafer 3. For instance, a 12-in wafer 3 can be sawed twice symmetrically into four identical wafer slices 30. Upon such an arrangement, the wafer slice 30 of the 12-in wafer 3 can fit to be packaged by the existing 8-in wafer package machinery. No additional cost should be spent in purchasing 12-in wafer package machinery.

In the present invention, for the wafer slice 30 is no more circular, a photo resist spin coater is not appropriate any more. In the present invention, a photo resist spray coater is relevant to perform the spray coating of the photo resist on the wafer slice. In the marketplace, the spray coater is ⅓ in price of the spin coater, and no wafer size limitation is enforced on the spray coater.

In the lithography process of the present invention, soft bake, exposure and development, and hard bake are included, in which a manual alignment exposure machine can be used to perform the exposure. Superior to the auto-alignment exposure machine, the manual alignment exposure machine is suitable to all sizes of wafers.

Further, the pattern of the wafer slice in accordance with the present invention can be a single-layer circuit, or a multi-layer circuit. In the case that the pattern is a multi-layer circuit, repeating the lithography process and the pattern-forming process as described above would be needed. Also, on the UBM, a layer of Zn and Ni can be chemically deposited in advance and then the solder balls can be implanted by a solder paste printing and reflow process.

In the present invention, any size of the wafer can be sawed into a plurality of the wafer slices having a proper size able to be packaged by existing package machines. Upon such an arrangement, additional cost for purchasing machinery for new-generation wafer size can be thus waived.

While the present invention has been particularly shown and described with reference to a preferred embodiment, it will be understood by those skilled in the art that various changes in form and detail may be without departing from the spirit and scope of the present invention.

I claim:

1. A method of wafer level chip size packaging, comprising the steps of:
grinding a wafer on a back surface thereof to a predetermined thickness;
sawing the wafer into a plurality of wafer slices;
spray coating a photo resist layer on top of the wafer slice;
applying a lithography process to form contact windows on the wafer slice;
forming a pattern on the wafer slice by printing or sputtering, in which bottom ends of the pattern are connected with the respective contact windows and an upper surface of the pattern forms protrusively a plurality of under bump metals (UBM);
spray coating a solder mask on top of the pattern;
applying another lithography process to form apertures on the respective UBMs;
implanting solder balls to the respective apertures; and
sawing the wafer slice into separate dies.

2. The method of wafer level chip size packaging according to claim 1, wherein said wafer is symmetrically sawed at least twice into more than four wafer slices.

3. The method of wafer level chip size packaging according to claim 1, wherein said lithography process includes the steps of soft bake, exposure and development, and hard bake.

4. The method of wafer level chip size packaging according to claim 1, wherein said pattern is a multi-layer circuit.

5. The method of wafer level chip size packaging according to claim 1, wherein said UBM is surfaced by a layer of Zn and Ni.

6. The method of wafer level chip size packaging according to claim 5, wherein said layer of Zn and Ni is formed by chemical deposition.

7. The method of wafer level chip size packaging according to claim 1, wherein said solder balls are implanted by a solder paste printing and reflow process.
